(19) United States
(12) Patent Application Publication
(10) Pub. No.: US 2024/0264306 A1
(43) Pub. Date: Aug. 8, 2024

(54) REFLECTIVE OPTICAL SENSOR

(71) Applicant: Dexerials Corporation, Tochigi (JP)

(72) Inventors: Akihiro TATEKOUJI, Tochigi (JP); Etsuji OMURA, Tochigi (JP)

(73) Assignee: Dexerials Corporation, Tochigi (JP)

(21) Appl. No.: 18/637,385

(22) Filed: Apr. 16, 2024

Related U.S. Application Data
(63) Continuation of application No. PCT/JP2021/038924, filed on Oct. 21, 2021.

(51) Int. Cl. G01S 17/04

(52) U.S. Cl. CPC G01S 17/04

(57) ABSTRACT

A reflective optical sensor, which detects an object to be detected by detecting light reflected by the object by means of a light emitting element and a light receiving element, has an case of an open box shape in which first and second concave mirrors each having a reflective parabolic surface are formed. These first and second concave mirrors are formed so that the symmetry axes of the first and second concave mirrors intersect with a predetermined intersection angle on opposite side to the apexes of the first and second concave mirrors with respect to first and second focal points of the mirrors. Light emitted by the light emitting element travels through the first concave mirror, the object, the second concave mirror and the light receiving element.

### CROSS-REFERENCE TO RELATED APPLICATION

This application is a continuation of the International PCT application serial no. PCT/JP2021/038924, filed on Oct. 21, 2021. The entirety of the above-mentioned patent application is hereby incorporated by reference herein and made a part of this specification.

### TECHNICAL FIELD

The present invention relates to a reflective optical sensor that detects an object to be detected by irradiating light and detecting the light reflected by the object to be detected.

### BACKGROUND ART

Conventionally, reflective optical sensors have been widely used to detect objects to be detected by irradiating light and detecting the reflected light from nearby objects. Reflective optical sensors can detect objects without contact, and are commonly used in applications such as rotation angle detection and object edge detection, for example.

A reflective optical sensor, for example as in Patent Document #1, has a light emitting element, a light receiving element, and a light blocking wall arranged between them, so that the light irradiated by the light emitting element is reflected by an object to be detected, and this reflected light is received by the light receiving element. And it uses changes in the output of the light receiving element, depending on the presence or absence of the reflected light and the intensity of the reflected light, for detecting the object to be detected.

### PRIOR ART DOCUMENTS

### Patent Documents

Patent Document #1: Japanese Patent Application Publication No. 2001-308372

### SUMMARY OF THE INVENTION

### Problems to Be Solved by the Invention

In the reflective optical sensor of Patent Document #1, the light emitting element irradiates diffuse light onto the nearby object to be detected. Therefore, most of the light emitted by the light emitting element is irradiated onto the object to be detected, but even if the object to be detected has a high reflectance, the amount of the light reflected by the object to be detected and incident on the light receiving element is small. For example, when coupling efficiency is defined as the ratio of light incident on the light receiving element to the light emitted by the light emitting element, the coupling efficiency is about 5% when the irradiation angle of the light emitting element is 90°, according to the results of ray tracing simulation in the reflective optical sensor in Patent Document #1, and therefore, improvement of coupling efficiency is desired.

An object of the present invention is to provide a reflective optical sensor that can improve coupling efficiency.

### Means to Solve the Problems

The present invention presents a reflective optical sensor comprising a light emitting element and a light receiving element, and detecting an object to be detected by reflected light emitted from the light emitting element and reflected by the object to be detected with the light receiving element; wherein provided is a case of an open box shape with a first concave mirror and a second concave mirror integrally formed at a bottom thereof, the first concave mirror and the second concave mirror each have a parabolic surface including an apex of a parabola formed by rotating the parabola around a symmetry axis of the parabola as a reflecting surface, and are formed with these reflective surfaces facing an open side of the case so that the symmetry axis of the first concave mirror and the symmetry axis of the second concave mirror intersect with a predetermined intersection angle on opposite side to the apex of the first concave mirror with respect to a first focal point of the first concave mirror and opposite side to the apex of the second concave mirror with respect to a second focal point of the second concave mirror, light emitted by the light emitting element toward the first concave mirror from a position at or near the first focal point is reflected by the first concave mirror and irradiated to the object to be detected, the reflected light reflected by the object to be detected is irradiated on the second concave mirror, and the light receiving element is configured to detect reflected light reflected by the second concave mirror so as to focus on the second focal point.

According to the above configuration, the light emitting element of the reflective optical sensor emits light toward the first concave mirror from the position at or near the first focal point of the first concave mirror, and the light reflected by the first concave mirror is irradiated to the object to be detected. The reflected light reflected by the object to be detected is irradiated onto the second concave mirror, and this reflected light reflected by the second concave mirror so as to focus on the second focal point, enters the light receiving element of the reflective optical sensor. The light emitted from the light emitting element is reflected by the first concave mirror to become collimated light due to the nature of parabolic surfaces, so that a constant light is irradiated to the object to be detected regardless of the distance to the object. When the irradiated collimated light is reflected by a flat reflective surface of the object to be detected, most of the reflected light is irradiated to the second concave mirror as collimated light, and is reflected and focused by the second concave mirror toward the second focal point. Therefore, most of the diffuse light emitted from the light emitting element is collimated and irradiated to the object to be detected, and the reflected light is focused and detected by the light receiving element, thereby improving coupling efficiency when the ratio of light incident on the light receiving element to the light emitted by the light emitting element is defined as coupling efficiency. In addition, since the collimated light is irradiated, a constant light can be irradiated regardless of the distance from the reflective optical sensor, and the range of distance between the object to be detected and the reflective optical sensor, where high coupling efficiency can be obtained, can be widened.

In a first preferable aspect of the present invention, the light emitting element and the light receiving element are housed in the case, and the case is filled with sealing resin through which the light from the light emitting element is transmitted. According to this configuration, the sealing resin protects the light emitting element, light receiving element, and reflective surfaces of the first and second concave mirrors to prevent damage to the reflective optical sensor due to collision with the object to be detected.

In a second preferable aspect of the present invention, the first concave mirror and the second concave mirror have a light blocking wall between them that prevents light from the light emitting element from entering directly into the second concave mirror and light reflected from the first concave mirror from entering directly into the light receiving element. According to this configuration, it is possible to to prevent misdetection of the object to be detected by preventing light from the light emitting element from entering the light receiving element without being reflected by the object to be detected.

### Advantages of the Invention

According to the reflective optical sensor of the present invention, coupling efficiency can be improved.

### BRIEF DESCRIPTION OF THE DRAWINGS

FIG. 1 is a plan view of a reflective optical sensor according to an embodiment of the present invention;

FIG. 2 is a cross-sectional view taken along the line II-II in FIG. 1;

FIG. 3 is a diagram of a parabola;

FIG. 4 is a diagram for assembling the reflective optical sensor;

FIG. 5 is an example of ray tracing simulation results for the reflective optical sensor according to the embodiment;

FIG. 6 is a diagram showing the relationship between distance h and coupling efficiency in the reflective optical sensor according to the embodiment;

FIG. 7 is a contour plot showing the relationship between distance h, angles of the first and second concave mirrors, and coupling efficiency in the reflective optical sensor according to the embodiment; and

FIG. 8 is a diagram showing the relationship between angles of the first and second concave mirrors, the focal lengths of the first and second concave mirrors, and coupling efficiency in the reflective optical sensor according to the embodiment.

### DESCRIPTION OF EMBODIMENTS

Hereinafter, the form for implementing this invention is demonstrated based on an Example.

### Embodiment

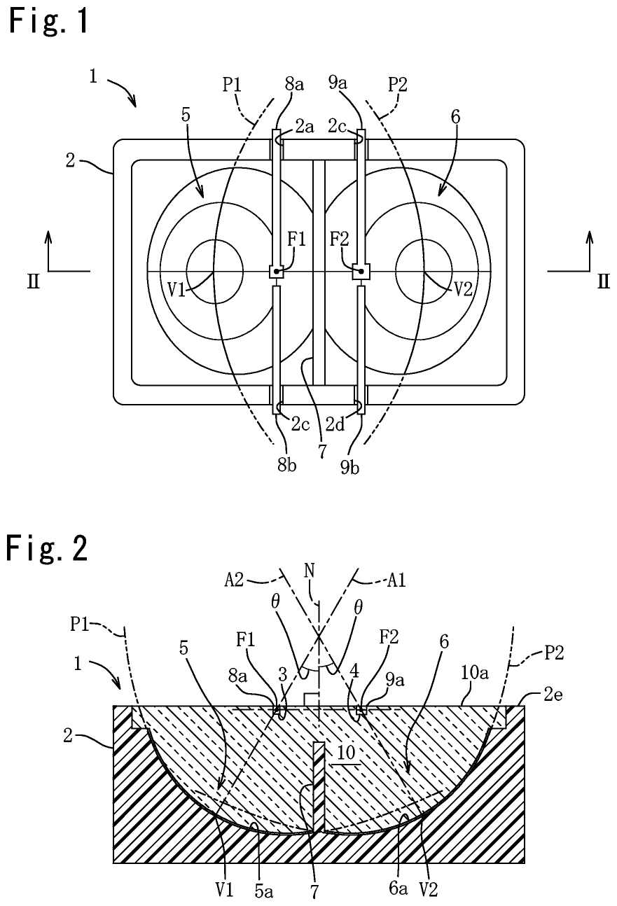

As shown in FIGS. 1 and 2, a reflective optical sensor 1 has a rectangular parallelepiped open box-shaped case 2 with an open top surface, a light emitting element 3, and a light receiving element 4. Although the open side of the case 2 will be described as the upper side of the reflective optical sensor 1, the reflective optical sensor 1 can be used in various postures depending on the application.

A first concave mirror 5 and a second concave mirror 6 are integrally formed on the inner bottom of the case 2 with their reflective surfaces facing the open side of the case 2. The first concave mirror 5 is a parabolic surface formed by rotating a parabola P1 around the symmetry axis A1 of the parabola P1, and is formed using the parabolic surface including the apex of the parabola P1 as a reflective surface. The second concave mirror 6 is a parabolic surface formed by rotating a parabola P2 around the symmetry axis A2 of the parabola P2, and is formed using the parabolic surface including the apex of the parabola P2 as a reflective surface.

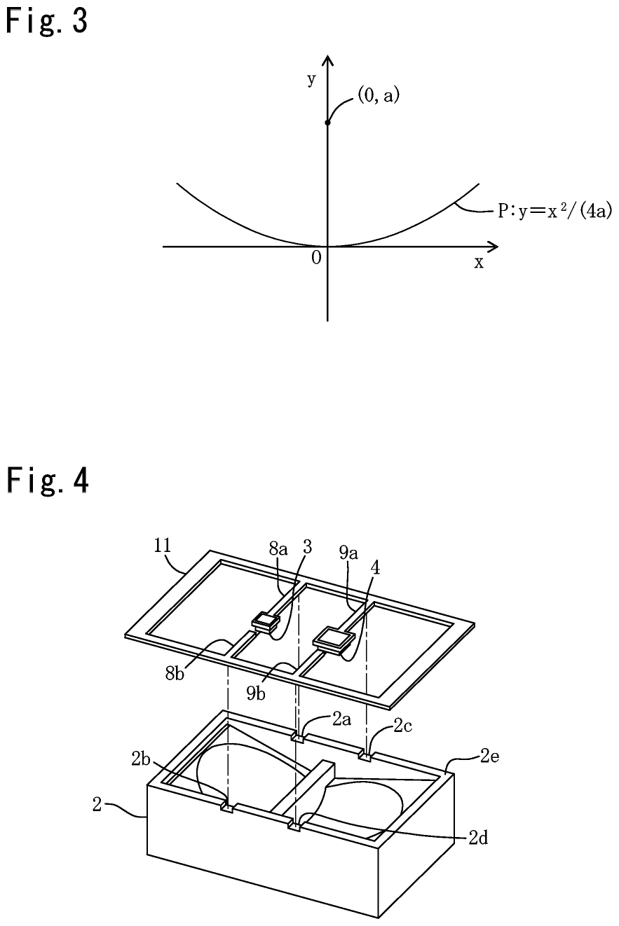

As shown in FIG. 3, in a parabola P expressed as y=x²/(4a) on the xy-plane, for example, a=5 mm gives the parabola P1, P2 (See FIG. 2), but the value of a may be different for the parabola P1 and P2. The y-axis is the symmetry axis of the parabola P, the position of the origin is the apex (vertex) of the parabola P, and the position of (x, y)=(0, a) is the focal point of the parabola P.

As shown in FIGS. 1 and 2, the apex of the parabola P1 forming the first concave mirror 5 is designated as the first apex V1, and its focal point is designated as the first focal point F1. Further, the apex of the parabola P2 forming the second concave mirror 6 is designated as the second apex V2, and its focal point is designated as the second focal point F2. The first concave mirror 5 and the second concave mirror 6 are formed so that the symmetry axis A1 of the parabola P1 and the symmetry axis A2 of the parabola P2 intersect at a specified intersection angle 2θ. The symmetry axis A1 passes through the first apex V1 of the parabola P1 and the first focal point F1. The symmetry axis A2 passes through the second apex V2 of the parabola P2 and the second focal point F2. The symmetry axes A1 and A2 should be symmetrically inclined at an angle θ each with respect to the directional axis perpendicular to the open end face 2e of the case 2 (with respect to the normal N of the open end face 2e passing through the intersection of the symmetry axes A1 and A2).

The symmetry axes A1 and A2 intersect at opposite side to the first apex V1 with respect to the first focal point F1 and at opposite side to the second apex V2 with respect to the second focal point F2. That is, the symmetry axis A1 and the symmetry axis A2 intersect at a position on the opposite side of the first and second apexes V1 and V2 and further apart than the first focal point F1 and the second focal point F2.

The case 2 is formed into a rectangular box shape with an open top surface by resin molding, for example, and parabolic surfaces with rotated parabolas P1 and P2 corresponding to the first and second concave mirrors 5, 6 are formed on the inner bottom, respectively. Then, reflective films 5a and 6a containing metals such as gold and titanium, for example, are respectively formed on at least these two parabolic surfaces, and the first and second concave mirrors 5 and 6 are integrally formed in the case 2. At the boundary between the first and second concave mirrors 5 and 6, a light blocking wall 7 extending from the inner bottom of case 2 toward the open side is formed to separate the first and second concave mirrors 5 and 6.

Recesses 2a to 2d are formed at the open end of the case 2, which are recessed from the open end face 2e of the case 2 toward the bottom for positioning a pair of first lead frames 8a, 8b and a pair of second lead frames 9a, 9b. The first lead frames 8a and 8b supply power to the light emitting element 3 from the outside. The light emitting element 3 is fixed to one side of the tip of the first lead frame 8a, which is placed and fixed in the recess 2a. The first lead frame 8a is fixed to the recess 2a so that the light emitting surface from which the light emitting element 3 emits light faces the first concave mirror 5 and the light emitting element 3 is positioned at or near the first focal point F1. The light emitting element 3 is housed in the case 2. Alternatively, the recesses 2a to 2d may not be formed and may be positioned using in other ways.

The second lead frames 9a and 9b output the optical power of the light receiving element 4 to the outside. The light receiving element 4 is fixed to one side of the tip of the second lead frame 9a, which is placed and fixed in the recess 2c. The second lead frame 9a is fixed to the recess 2c so that the light receiving surface of the light receiving element 4, which allows light to enter, faces the second concave mirror 6 and the light receiving element 4 is positioned at or near the second focal point F2. The light receiving element 4 is housed in the case 2.

As shown in FIG. 2, the case 2 housing the light emitting element 3 and the light receiving element 4 is filled with sealing resin 10, and the light emitting element 3 and the light receiving element 4 are covered by the sealing resin 10. The first lead frames 8a, 8b and the second lead frames 9a, 9b may also be covered by the sealing resin 10. The sealing resin 10 is an epoxy-based synthetic resin that has a translucent property that allows the light from the light emitting element 3 to pass through, for example, visible or infrared light. The sealing resin 10 protects the light emitting element 3, the light receiving element 4, and the reflective surfaces of the first and second concave mirrors 5 and 6, and restricts the swinging of the light emitting element 3 and the light receiving element 4. For example, when external vibrations are not transmitted to the light emitting element 3 and the light receiving element 4, the sealing resin 10 may be omitted.

The surface 10a of the sealing resin 10 is formed flat so as to coincide with the open end face 2e of the case 2. The surface 10a of the sealing resin 10 is a plane in the vicinity of the first and second focal points F1 and F2 that is parallel to the plane containing the first and second focal points F1 and F2. Then, the intersection of the symmetry axis A1 and the symmetry axis A2 above the surface 10a of the sealing resin 10 and a region near this intersection become a detection position of the object to be detected.

The first lead frames 8a, 8b and the second lead frames 9a, 9b are elongated members respectively made of, for example, Kovar (an alloy containing iron, nickel, and cobalt), so it is not easy to attach them individually to the case 2. Therefore, as shown in FIG. 4, the light emitting element 3 and light receiving element 4 are fixed and connected electrically by bonding wires, for example, to the first lead frames 8a, 8b and second lead frames 9a, 9b, which are integrally formed with a rectangular frame 11. Then, the first lead frames 8a, 8b and the second lead frames 9a, 9b are placed in the corresponding recesses 2a to 2d together with the frame 11 at the same time. After sealing with the sealing resin 10, the frame 11 is cut off and removed by cutting the base end portions of the first lead frames 8a, 8b and the second lead frames 9a, 9b.

The frame 11 with the first lead frames 8a, 8b and the second lead frames 9a, 9b can also be formed in tape or sheet form so that the frame 11 is continuous in a plane. In this case, the light emitting element 3 and light receiving element 4 can be easily fixed and electrically connected, and can be attached continuously or simultaneously to a plurality of cases 2 arranged at predetermined intervals, for example, thus improving manufacturing efficiency.

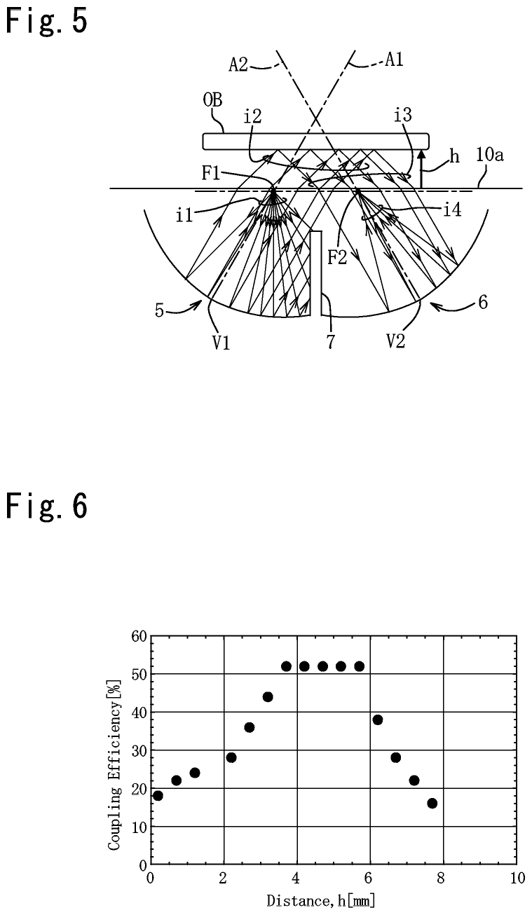

As shown in FIG. 5, due to the nature of the parabola, a part of light i1 emitted from the light emitting element 3 at or near the first focal point F1 can be reflected by the first concave mirror 5 and can be emitted as light i2 (collimated light) to an object OB to be detected. The light blocking wall 7 prevents light emitted from the light emitting element 3 from entering directly into the second concave mirror 6 and also prevents light reflected by the first concave mirror 5 from entering directly into the light receiving element 4. The light emitting element 3 is a light emitting diode with an irradiation angle of 90°.

When there is the object OB to be detected with a flat reflective surface parallel to the surface 10a of the sealing resin 10 of the reflective optical sensor 1 at the detection position, reflected light i3 (collimated light), in which the light i2 is reflected by the object OB to be detected, is irradiated to the second concave mirror 6. At this time, if the symmetry axes A1 and A2 are symmetrically inclined at the same angle with respect to the surface 10a, it is easy to set the reflective surface of the object OB to be detected and the surface 10a of the reflective optical sensor 1 so that they are parallel. Even if the symmetry axis A1 and the symmetry axis A2 are not symmetrically inclined at the same angle with respect to the surface 10a, the object OB to be detected can be detected by setting it so that the reflective surface of the object OB to be detected is inclined with respect to the surface 10a.

The reflected light i3 is reflected by the second concave mirror 6 toward the second focal point F2 and is focused as reflected light i4. Then, the reflected light i4 enters the light receiving element 4 at or near the second focal point F2, and a photocurrent is output. On the other hand, when there is no object OB to be detected, the light i2 reflected by the first concave mirror 5 from the light emitting element 3 does not enter the second concave mirror 6 and goes outside, so it does not enter the light receiving element 4. Therefore, the reflective optical sensor 1 can detect the object OB to be detected by reflecting the reflected light i3, which is emitted the light emitting element 3, reflected by the object OB to be detected with the second concave mirror 6 and detecting this reflected light i4 with the light receiving element 4.

When coupling efficiency is defined as a ratio of light incident on the light receiving element 4 with respect to light emitted by the light emitting element 3, the higher the coupling efficiency, the greater the photocurrent output of the reflective optical sensor 1. Therefore, it is desirable to achieve high coupling efficiency because, for example, misdetection of object OB to be detected due to stray light can be easily prevented and, for example, the light intensity of the light emitting element 3 can be lowered to achieve low power consumption. Here, based on the ray tracing simulation as shown in FIG. 5, coupling efficiency when the object OB to be detected is separated from the surface 10a is shown in FIG. 6, using a distance h between the surface 10a of the reflective optical sensor 1 and the detected object OB to be detected as a parameter.

As the distance h increases, the coupling efficiency increases until h=3.7 mm, after which the coupling efficiency becomes constant at 52%. Furthermore, as the distance h increases, the coupling efficiency decreases. The coupling efficiency is maximum within the distance h of 3.7 mm to 5.7 mm, and high coupling efficiencies exceeding 10% are obtained from the distance h of 0 mm to about 8 mm. Therefore, high coupling efficiency can be obtained even when a certain distance h is secured to prevent damage to the reflective optical sensor 1 and the object OB to be detected due to contact between the reflective optical sensor 1 and the object OB to be detected. Furthermore, the reflected light is decreased in a case where an object OB to be detected is smaller than the range of the collimated light to be irradiated, but the coupling efficiency is high enough to detect the small object OB to be detected.

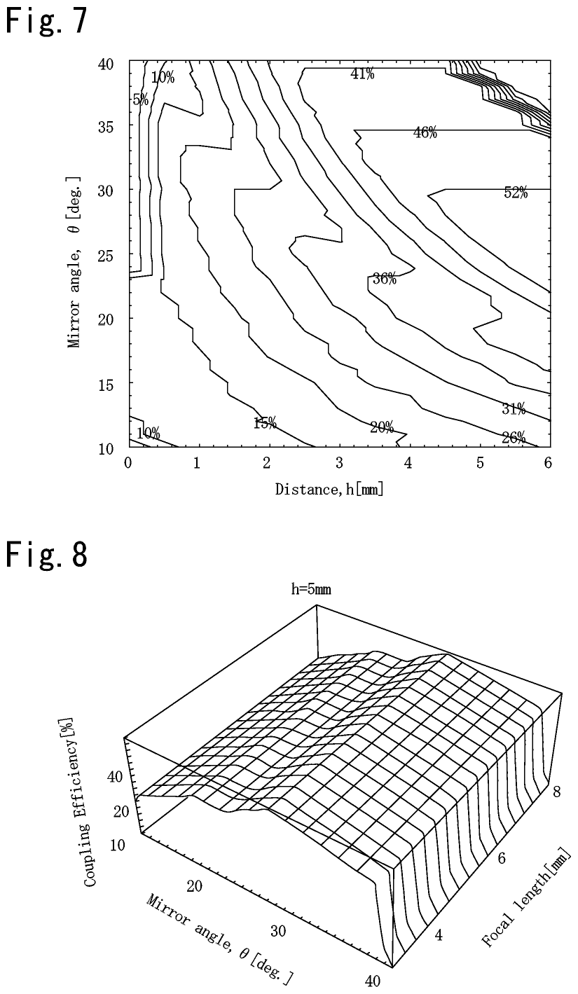

The coupling efficiency with the distance h and the angle of inclination of the symmetry axes A1 and A2 (angle of inclination of the first and second concave mirrors 5, 6) θ as parameters is shown in FIG. 7 as contour plots. As the angle θ increases, the range of the distance h where high coupling efficiency can be obtained shifts in the direction where the distance h becomes smaller. When the angle θ is increased to some extent, the coupling efficiency drops sharply because most of the light reflected by the first concave mirror 5 is blocked by the light blocking wall 7 so that it does not enter directly into the light receiving element 4 and is not irradiated to the object OB to be detected. When the distance h is set, the reflective optical sensor 1 can be formed at an angle θ that results in high coupling efficiency based on FIG. 7. For the reflective optical sensor 1 with the angle θ, the optimal distance h can be specified that results in high coupling efficiency.

When the distance h is 5 mm, the coupling efficiency with the angle θ of inclination of the first and second concave mirrors 5, 6 and the focal length as parameters is shown in FIG. 8 as a curved surface. The coupling efficiency is not affected hardly by the focal lengths of the first and second concave mirrors 5, 6, and is maximum when the angle θ is 25° at any focal length.

The functions and effects of the reflective optical sensor 1 described above will be explained. In the reflective optical sensor 1, the light emitting element 3 emits light i1 toward the first concave mirror 5 from the position at or near the first focal point F1 of the first concave mirror 5, and the light i2 reflected by the first concave mirror 5 is emitted onto the object OB to be detected. The reflected light i3 reflected by the object OB to be detected is irradiated to the second concave mirror 6, and the reflected light i4 reflected by the second concave mirror 6 to be focused toward the second focal point F2 is incident on the light receiving element 4.

The light i1 emitted from the light emitting element 3 is reflected by the first concave mirror 5 and becomes a collimated light due to the nature of the parabolic surface, so that a constant light i2, which is independent of the distance from the reflective optical sensor 1, is emitted and reflected by the object OB to be detected. Most of the reflected light i3 reflected from the flat reflective surface of the object OB to be detected is irradiated in collimated light to the second concave mirror 6, which reflects and focuses the light toward the second focal point F2. Thus, since most of the diffuse light emitted from the light emitting element 3 can be collimated and irradiated to the object OB to be detected, and its reflected light i3 can be focused and detected by the light receiving element 4, the coupling efficiency can be improved when the ratio of the light incident on the light receiving element 4 with respect to the light emitted by the light emitting element 3 is defined as the coupling efficiency. In addition, since collimated light is irradiated, it is possible to irradiate a constant light which is independent of the distance from the reflective optical sensor 1 to the object OB to be detected. Therefore, the range of distance h between the object OB to be detected and the reflective optical sensor 1, where high coupling efficiency can be obtained, can be widened.

Furthermore, the light emitting element 3 and light receiving element 4 are housed in the case 2, and the case 2 is filled with sealing resin 10 through which the light of the light emitting element 3 is transmitted. Therefore, the sealing resin 10 protects the light emitting element 3, the light receiving element 4, and the reflective surfaces of the first and second concave mirrors 5, 6 to prevent damage to the reflective optical sensor 1 due to collision with, for example, the object OB to be detected.

The reflective optical sensor 1 has the light blocking wall 7 between the first concave mirror 5 and the second concave mirror 6, which prevents light from the light emitting element 3 from entering directly into the second concave mirror 6 and light reflected by the first concave mirror 5 from entering directly into the light receiving element 4. Therefore, it is possible to prevent light of the light emitting element 3 from entering the light receiving element 4 without being reflected by the object OB to be detected, thereby preventing misdetection of the object OB to be detected.

Although the figures are omitted, instead of the first lead frames 8a, 8b and the second lead frames 9a, 9b, the light emitting element 3 and the light receiving element 4 can be fixed to a lid member transparent to the light of the light emitting element 3, and a plurality of wires electrically connected to these light emitting element 3 and light receiving element 4 can be formed on the lid member and this lid member fixed to the open side of the case 2. In addition, those skilled in the art can implement various modifications to the embodiment described above without departing from the purpose of the present invention, and the present invention includes such modifications.

1. A reflective optical sensor comprising a light emitting element and a light receiving element, and detecting an object to be detected by reflected light emitted from the light emitting element and reflected by the object to be detected with the light receiving element; wherein
provided is a case of an open box shape with a first concave mirror and a second concave mirror integrally formed at a bottom thereof,
the first concave mirror and the second concave mirror each have a parabolic surface including an apex of a parabola formed by rotating the parabola around a symmetry axis of the parabola as a reflecting surface, and are formed with these reflective surfaces facing an open side of the case so that the symmetry axis of the first concave mirror and the symmetry axis of the second concave mirror intersect with a predetermined intersection angle on opposite side to the apex of the first concave mirror with respect to a first focal point of the first concave mirror and opposite side to the apex of the second concave mirror with respect to a second focal point of the second concave mirror,
light emitted by the light emitting element toward the first concave mirror from a position at or near the first focal point is reflected by the first concave mirror and irradiated to the object to be detected,
the reflected light reflected by the object to be detected is irradiated on the second concave mirror, and
the light receiving element is configured to detect reflected light reflected by the second concave mirror so as to focus on the second focal point.

2. The reflective optical sensor according to claim 1; wherein the light emitting element and the light receiving element are housed in the case, and the case is filled with sealing resin through which the light from the light emitting element is transmitted.

3. The reflective optical sensor according to claim 1; wherein the first concave mirror and the second concave mirror have a light blocking wall between them that prevents light from the light emitting element from entering directly into the second concave mirror and light reflected from the first concave mirror from entering directly into the light receiving element.
